(19) United States
(12) Patent Application Publication
(10) Pub. No.: US 2010/0319755 A1
(43) Pub. Date: Dec. 23, 2010

(54) Solar Augmentation System

(76) Inventors: Dan O'Connell, Wailuku, HI (US); Terry Born, Wailuku, HI (US)

Correspondence Address: MORGAN LEWIS & BOCKIUS LLP, 1111 PENNSYLVANIA AVENUE NW, WASHINGTON, DC, 20004, US

(21) Appl. No.: 12/852,731

(22) Filed: Aug. 9, 2010

Related U.S. Application Data
(62) Division of application No. 12/078,420, filed on Mar. 31, 2008, now abandoned.

(51) Int. Cl. H01L 31/052; H01L 31/042

(52) U.S. Cl. 136/246; 136/244

(57) ABSTRACT

The present invention relates to a solar panel condenser apparatus that includes an optical condenser and a photovoltaic cell. The optical condenser may be two or more stages of Fresnel lenses. The optical condenser may also include one or more optical devices to separate sunlight into frequency bands so that light of different frequency bands falls on photovoltaic cells appropriate to the frequency band.

### RELATED APPLICATION

This application claims priority of copending Provisional Application No. 60/907,404 filed on Mar. 30, 2007; U.S. application Ser. No. 11/512,418 filed Aug. 30, 2006; and U.S. application Ser. No. 11/889,369 filed on Aug. 13, 2007; the entire contents of which are hereby incorporated by reference.

### INCORPORATION-BY-REFERENCE OF MATERIAL SUBMITTED ON A COMPACT DISC

Not applicable.

### SEQUENCE LISTING

Not applicable.

### BACKGROUND OF THE INVENTION

1. Field of the Invention

The present invention relates generally to the field of photovoltaics, and more specifically to an apparatus for increasing the power output of photovoltaic cells.

2. Description of Related Art

A solar cell is a semiconductor device that converts incident photons from the sun (solar radiation) into useable electrical power. The general term for a solar cell is a photo-voltaic (PV) cell. The output of a conventional PV solar cell is limited to approximately 10% efficiency and as much as 17% to 20% in high end single crystal silicon solar panels. Single crystal silicon PV cells have a higher efficiency than polycrystalline silicon; however, they are considerably more expensive.

A traditional PV cell consists of a single layer p-n junction made of single crystal silicon. Lower cost poly-crystal silicon material is now being used in these traditional PV cells, but at the cost of lower efficiency. Incident photons cause the photoelectric effect by raising electrons into a region in the material known as the conduction band where the electrons are free to flow as current. When the material is connected with an external circuit, the photo-generated current can be used as electrical power.

A new generation of solar cells uses multiple layers of p-n junction diodes, each layer designed to absorb a successively longer wavelength (lower energy) photon of light energy that penetrates deeper into the material, thus absorbing more of the solar spectrum and increasing the amount of electrical energy produced. Such new generation PV cells can have efficiencies of around 20%, with efficiencies of as much as 30% being demonstrated in research laboratories. These research projects use very expensive multiple layer PV material that may not reach the consumer for many years to come.

The low efficiency (10-20%) that exists in PV solar cell technology is attributed to a narrow spectral range of solar radiation (FIG. 1) incident on the solar cell that is absorbed, thus resulting in usable electric current. The host crystal is doped with two specific materials, one having an excess outer valence electron (n-material) and the other lacking an outer valence electron (p-material). The boundary between the doped layers forms the p-n junction that establishes an electrical barrier or energy bandgap. As described in equation 1, electrons in the n-material must be excited with sufficient energy by an incident photon to cross the bandgap and enter the conduction band, which effectively sweeps free electrons away as useable current.

E_{g}ltoreq·hv Equation 1

(Where E is the Energy in a Photon of Frequency v, and h is Plank's Constant)

Long wavelengths in the near infrared and infrared range are outside the usable spectral range because they are transmitted through the material or deep into the material beyond the desired absorption layer. Shorter wavelengths in the ultraviolet and blue range are more readily absorbed by the semi-conductor; as a result higher energy photons do not reach the desired n-doped absorption region. Therefore, only a limited spectral band of incident solar radiation is used by existing photo-voltaic solar cells.

Typical PV material used as a solar cell for power generation is used in a forward bias configuration. As described in Equation 2, the photo-generated current (i_{g}) is linearly proportional to the number of incident photons over a large range.

i_{g}=·eta·qA_{d}E_{q} Equation 2

E_{q}—photon irradiance in photons per second per square meter.

quantum efficiency of the material

q—charge on an electron

A_{d}—area of the detector or solar cell

A certain number of electrons that are generated do not contribute to useable current. These noise electrons (or, in terms of current, noise current) limit the output of a solar panel. Some of the noise current is generated when the material operates at elevated temperatures, such as would occur in hot climates.

Attempts, such as those discussed above, have been made to improve the output of PV cells. However, these modifications to PV material and PV cell configuration have resulted in only modest improvements in PV cell output, at least with respect to that of the traditional PV cell.

U.S. Pat. No. 4,892,593 is directed to a solar energy collector which includes, among other features, a light funneling trough containing a pair of light reflecting surfaces extending from an apex line in an oblique angle, a two dimensional Fresnel lens, and a PV panel facing the Fresnel lens. Given its complex mechanical configuration, the solar energy collector is relatively expensive to manufacture, and the collector is not mounted in close proximity to the PV panel.

U.S. Pat. No. 6,958,868 is directed to a solar collector for concentrating solar radiation consisting of a Fresnel lens and one or more arrays of prismatic cells. The light rays are directed to the focal point of the optic. As with U.S. Pat. No. 4,892,593, this solar collector is expensive and volumetrically inefficient.

U.S. patent application Ser. No. 11/512,418 discloses a light collector that is larger in collection aperture than the solar cell (FIG. 2). The solar condenser optic increases the effective area of the solar cell by a factor of any practical magnification ratio, thereby increasing the number of photons contributing to photo-generated electrons or usable current.

Any given solar cell has a limited spectral response for which photons are converted to useable photo-current. This is due to the bandgap within the semiconductor. Silicon based solar cells have a cutoff at approximately 1 micron wavelength and do not use incident photons that have a longer wavelength. There are materials being used to capture a portion of the solar spectrum in the infrared. These materials do not make use of available photons or energy at visible wavelengths. The temperature of the sun is approximately 6000 Kelvin which can be approximated as a black body radiator at that temperature. With the exception of atmospheric absorption and other scattering and absorption phenomenon, the spectral radiant flux from the sun can be approximated by computing Planck's Black Body Radiation formula. The peak energy from the sun is at 500 nm which is green light.

There are some solar cell developments that produce multiple layers of semiconductor material (multi-junction or the triple junction for example) in order to capture a larger portion of the solar spectrum and therefore increase the efficiency of energy conversion of a given solar cell. Often when a single device is made more complex, perfoiivance in either region is sacrificed. It is less costly and more efficient to maximize the performance of a semiconductor device within its operating region.

Thus, there remains a need to improve the output of PV cells and do so in a cost and space efficient manner.

### SUMMARY

Accordingly, the present invention is directed to a solar panel condenser that substantially obviates one or more of the problems due to the limitations and disadvantages of the related art.

An object of the invention relates to a solar panel condenser apparatus comprising an optical condenser including a Fresnel lens and a PV cell mounted substantially parallel to the optical condenser and placed about midway between the optical condenser and the focus of the optical condenser.

In one embodiment, the optical condenser has a second Fresnel lens.

In other embodiments, the optical condenser includes a collimator lens or a solid immersion lens.

In other embodiments of the invention, the condenser includes two or more PV cells and at least two beam splitters to divide the light into multiple bands of light according to wavelength, each of which band of light is directed to one of the PV cells.

In yet other embodiments of the invention, the solar panel condenser apparatus further includes a tracking spherical light trap that separates admitted light into multiple bands of light according to wavelength. The spherical light trap may comprise an entrance aperture, a light reflective baffle, and one or more ports, adjacent to which ports are located the PV cells. The PV cells may be constructed of materials optimized for the band of admitted light that passes through a bandpass lens. The interior surface of the light trap may be coated with a reflective material.

In still another embodiment of the invention, a multi-band solar cell stack is constructed of a first solar cell fabricated of a material optimized for a portion of the solar spectrum and a second solar cell fabricated of a material optimized for a different portion of the solar spectrum, with the first solar cell is thin enough that the portion of the solar spectrum not absorbed by the first solar cell passes through the first solar cell to the second solar cell.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

FIG. 1 is a graphical depiction of a measured solar spectrum and calculated blackbody radiation, based on a 6,000 degree Kelvin blackbody.

FIG. 2 is a general diagram of the solar panel condenser apparatus concept according to the invention.

FIG. 3 is a rear view of an embodiment of the solar panel condenser apparatus.

FIG. 4 is top view of an embodiment of the solar panel condenser apparatus.

FIG. 5 is a view of the solar panel condenser apparatus with a focal ratio (F/number) of F/0.5.

FIG. 6 is a view of the solar panel condenser apparatus with an focal ratio of F/0.25.

FIG. 7 is a view of an embodiment of the solar array, wherein the separation distance between the optical condenser and the PV panel is about 3 inches and the focal ratio is F/1.

FIG. 8 is a view of an embodiment of the compact solar condenser with a 2 inch separation and a focal ratio of F/1.

FIG. 9 is a view of an embodiment of the invention, which is described as a solar tower.

FIG. 10 is a side view of a solar panel condenser reducer according to the present invention.

FIG. 11 is a side view of a solar panel condenser reducer with a collimator according to the present invention.

FIG. 12 is a side view of a solar panel condenser without a solid immersion lens according to the present invention.

FIG. 13 is a side view of the solar power condenser of FIG. 12 with a solid immersion lens added.

FIG. 14 is a side view of a solar cell power condenser with a band splitter according to the present invention.

FIG. 15 is a side view of a solar cell power condenser with two band splitters according to the present invention.

FIG. 16 is a section view of a solar sphere and solar cell power condenser according to the present invention.

FIG. 17 is a general diagram of a thinned solar cell capturing a larger portion of the solar spectrum.

FIG. 18 is a side view of a solar cell stack according to the present invention.

FIG. 19 is a side view of a faceted funnel concentrator according to the present invention.

FIG. 20(a) is a perspective view of a solar cell with a capacitive electrical storage unit according to the present invention.

FIG. 20(b) is a side view of the solar cell of FIG. 20(a).

FIG. 21 is a semiconductor solar cell device that contains additional semiconductor structures and gates to enable the storage of electrical charge according to the present invention.

FIG. 22 is a side view of a solar roof system according to the present invention.

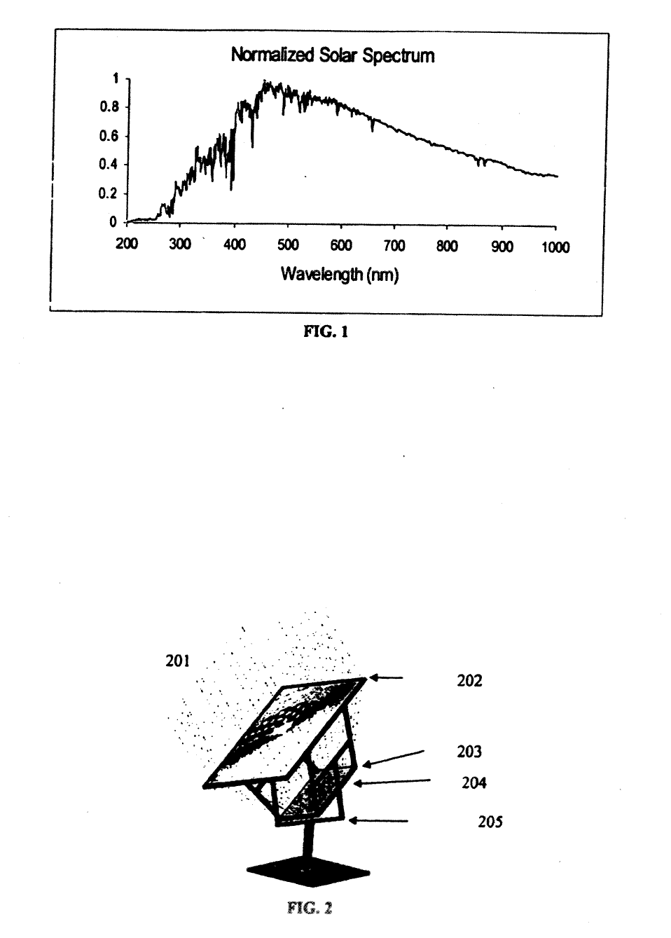

### DETAILED DESCRIPTION

Reference will now be made in detail to the preferred embodiments of the present invention, examples of which are illustrated in the accompanying drawings. FIG. 2 is an embodiment of the solar panel condenser apparatus that incorporates an optical condenser that is larger in collection aperture than the solar cell. The optical condenser (or solar condenser optic) can increase the effective area of the solar cell by a factor of about 2, preferably about 3, or more preferably about 4 (or any practical magnification ratio), therefore increasing the number of photons contributing to photo-generated electrons or usable current.

Solar energy does not generate sufficient current in typical solar cells to raise the material into saturation condition. Accordingly, use of a larger collecting optic can result in increased current output. As is evident from Equation 2, the increase in current, which can result from using an optical condenser, is linear over a large range prior to saturation. This is because the current is linearly proportional to the increased number of photon hits that result from use of the optical condenser. The increased number of photon hits occurs through the increase in effective area of the PV cell panel. Increased irradiance on the solar cell material will also raise the temperature of the solar cell, which in turn increases the number of electrons in the PV material that do not contribute to usable current, thus contributing to noise. This thermal heating reduces the available electrons for output current.

In one embodiment of the invention shown in FIG. 2, the solar panel condenser apparatus includes an optional cooling system or cold plate 204 that reduces the temperature of the PV material, thereby reducing electron noise and increasing usable current. FIG. 2, which depicts this embodiment, shows incident solar radiation 201 emanating through optical condenser 202 unto PV cell (or solar panel) 203. Cold plate, or cooling system, 204 is in contact with PV cell 203 and is used to transfer heat away from the PV cell to reduce the increased temperature effect stated above and thus minimize unwanted noise. Consequently, this increases operating efficiency. FIG. 2 also shows the presence of optional tracking base 205, which is discussed in more detail below.

The solar panel may be constructed of a coated glass faceplate mounted in a rugged vinyl frame. The vinyl frame is an innovative approach over aluminum frames available on the market today. The design described herein uses a specially designed extruded vinyl frame that includes conduit and bus wire internal to the frame.

A row of solar panels may be mounted to a bar along the back side of each solar panel in the center. The bar may have a lead screw that is driven by a small motor at the end of the row of panels. The row of panels may be tilted in the direction of the sun to achieve maximum collection area throughout the day. The maximum travel in either direction may be adjusted to suit the mounting location and solar angle. A lead jack may be used at the end of each row of solar panels to tilt the row of panels to maximize the collection area depending on the latitude on earth and the time of year. This simple lead screw device may improve the collection efficiency by 30% when the sun is 45 degrees from zenith or approximately 9 am and 3 pm.

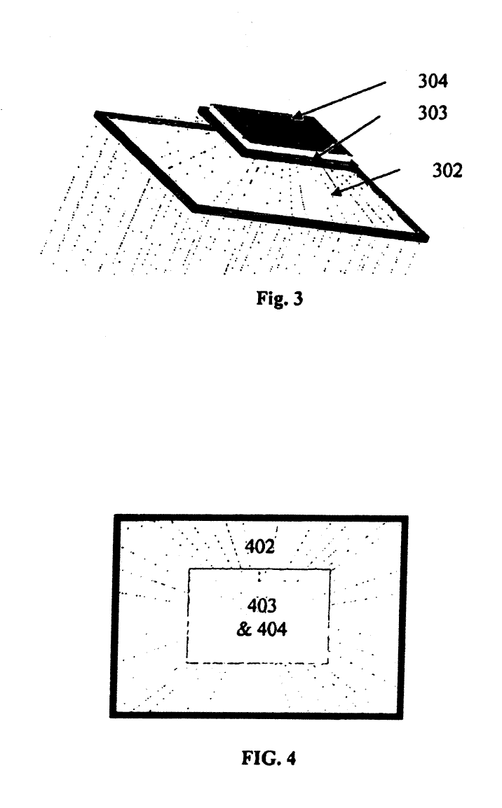

FIG. 3 provides a rear view of an embodiment of the solar panel condenser that includes cooling system 304 in addition to PV cell 303 and optical condenser 302. Cooling system 304 can include a heat sink, a cold plate or a cooling jacket, and can operate to minimize thermally generated charge carriers that are recombined with “holes” in the semi-conductor and thus do not contribute to current. As discussed, the larger effective collection area of the solar condenser has the tendency to raise the temperature of the PV substrate. The cooling system can therefore be used to lower the temperature of the PV substrate and thus minimize the adverse effect associated with this larger effective collection. Accordingly, use of a cooling system maximizes the benefit of the larger aperture condenser.

In another embodiment of the invention, the solar panel condenser apparatus may comprise a solar tracking drive to allow the solar panel condenser apparatus to face the sun throughout the day and thus maintain maximum collection of incident solar energy. This embodiment can be seen in FIG. 2. A stationary solar panel only reaches maximum potential output at one point during the day. The collection area of a stationary panel is the cross-sectional area normal to the sun and follows a cosine function throughout the day. The effective collecting area of a stationary panel is reduced to 70% when the sun is at 45 degrees from its maximum elevation, 50% when the sun is at 60 degrees declination, reducing to a few percent during morning and evening hours. Thus, a tracking drive which can adjust the position of the solar panel condenser apparatus throughout the day can maintain the effective collecting area of a PV cell at or near maximum efficiency.

Since the optical condenser is not an imaging optic but rather a light collecting and condenser optic, it can be made with a very short focal length in order to minimize the separation between the solar condenser and solar cell to a few inches or less. The optical condenser can take the form of a Fresnel lens, a computer generated holographic optic, or any other refractive, reflective, diffractive or hybrid optical element. The primary goal of the condenser optic is to collect solar energy over a larger effective area than the area of the solar panel by condensing the light onto the PV solar cell. The solar condenser/magnifier can be machined, molded, pressed or etched into glass plastic or other optically transparent substrate.

The lenses used in the optical condenser may consist of molded plastic or any other material type including glass and may take the form of a conventional lens or a thin Fresnel type lens. Each lens in the lens array may take the form of a plano-convex, bi-convex, meniscus lens shape including spherical or aspheric surfaces. The lenses may take a hybrid form where one side of the ones is a conventional thick lens having a curved surface either spherical or aspherical and the second surface be a Fresnel lens. The Fresnel lens may be applied to a curved surface to reduce the Fresnel groove density. The lens may take the form of a diffractive surface or holographic surface. The lens array may take the form of a Solid Immersion Lens where the curved surface of the lens is hemispherical or nearly hemi-spherical. Significant concentration gain can be achieved in a thin compound solar condenser cell array. Each individual Solar Condenser Cell can be made in 6 inch×6 inch square Solar cells and be assembled into any size PV module. The size of the individual Solar Condenser Cell can range from 1-inch×1-inch up to 12-inch×12-inch square or larger. An array of Solar Condenser Cells can be assembled into a larger PV module.

Other Solar power generation systems use reflective mirror technology which requires a collection device to be located in front of the mirror, therefore obscuring usable solar energy. In these systems, the distance between the light collector and solar absorber can be significant, making it impractical for individual home use or roof top mounted systems.

The solar panel condenser invention integrates a conventional solar cell (of any type or manufacturer), a large aperture optical (or solar) condenser, which increases the effective collection surface area of the PV solar cell or panel, as well as an optional cooling jacket to reduce the temperature of the PV material and increase the output of usable electric current.

In other embodiments, the apparatus also incorporates an optional solar tracker (for certain applications) which keeps the system directed towards the sun, therefore maintaining maximum projected surface area.

The solar panel condenser innovation increases the light gathering of an existing solar panel and increases the current output by a factor of 2 (i.e., 100% increase in output) as demonstrated in a prototype system. Additional current gain can be achieved in an optimized system up to a potential limit of 4. An optical condenser that is 2 times larger on a side will have 4 times the collection area (See FIG. 4). Since PV solar cells typically do not operate in a saturated condition, the power output of a solar panel can be increased by increasing the collection area of existing solar panels. A larger optical condenser can be fabricated using inexpensive plastic material that is highly transmissive over a large wavelength range. The condenser material can be any optical material, and is not limited to glass or plastic. The condenser optic is designed to bend light rays that fall outside the area of the solar cell and redirect them to intercept the solar cell. Optical material such as glass or plastic used in transmission as a light collector or lens will suffer from approximately 5% light loss from reflections at each surface.

In one embodiment of the invention, the optical condenser uses broad-band anti-reflection coatings to reduce reflected light from the surface of the collector from approximately 5% to less than 1%. The optical condenser used in transmission configuration can take the form of a Fresnel lens, a modified Fresnel lens, or a general diffractive optic, or a hybrid refractive (or reflective) and diffractive optic. The solar panel condenser invention uses a very fast optic or very short focal length or low F/number. The optical condenser is not used as an imaging optic; therefore, very short focal lengths are possible in order to bring the optical condenser as close as possible to the solar cell itself. The optical condenser can thus be built directly into the solar panel framework, replacing the existing cover glass of a solar panel. In a preferred embodiment, the optical condenser is substantially oriented in a single plane. This facilitates building the optical condenser directly into the solar panel framework.

The PV cell is mounted substantially parallel to the optical condenser and placed about midway between the optical condenser and the focal point of the optical condenser. The inventors have discovered that this feature unexpectedly offers several advantages. For example, locating the PV cell in this position reduces the spacing between the elements, thus resulting in a more compact arrangement. This location of the PV cell also substantially reduces the temperature of the PV cell material, thus resulting in a higher efficiency. If the material operated at elevated temperatures, as would occur if the PV cell were located closer to the focal point of the optical condenser, excess noise electrons would be generated. Higher operating temperatures create thermally generated charge carriers that recombine within the PV cell material. This in turn creates noise current and reduces the amount of useable electrical power generated. Operating at increased temperatures also reduces the lifetime of the PV cell material. The elevated operating temperatures allow the material to become saturated, therefore not allowing all of the captured light to be converted into useable electrical power. Such saturation occurs when the concentrated photon flux reaches a certain level. Since the current output of a PV cell is linearly proportional to the number of incident photons over a certain operating range, when the incident photon flux reaches a certain level the material will saturate, thus preventing current from being produced with additional incident photons.

Additionally, locating the PV cell about midway between the optical condenser and its focal point allows the user to rely upon only a single lens element as opposed to using additional optical elements which would be necessary in systems where the solar cell is placed at or near the focal point. Accordingly, locating the PV cell about midway between the optical condenser and its focal point requires less optics, thus reducing volume, complexity and cost.

The unique location of the PV cell in the embodiments of the present invention also allows for the use of lower quality lenses, which results in a cost savings. Locating the PV cell about midway between the optical condenser and its focal point results in a more uniform distribution of the light rays. Aberrations exist in a single element Fresnel lens which produce non-uniform energy distribution at or near the focus, including, for example, a spherical aberration or a chromatic aberration. Such aberrations are optical effects that spread light rays, redistributing energy as they approach the focal point of a lens. This redistribution of energy creates regions of increased energy and other regions of reduced energy, thereby creating hot spots in a PV cell substrate. By placing the PV cell midway to the focal point, the aberrations do not have the full impact on the light rays. Therefore, the distribution of light energy on the PV cell is more uniform, resulting in greater efficiency and performance. Accordingly, lower quality Fresnel lenses can be used. The use of lower quality lenses reduces lens cost and allows for the use of a focal length or F-number in a Fresnel lens of less than F/1, and potentially as low as F/0.5. This is due to the fact that aberrations in the PV cell arrangement of the present invention do not affect the distribution of energy as much as would occur with a system in which the PV cell is located at or near the focus. Uniformity of illumination enhances the performance, resulting in optimal operating conditions and therefore maximum efficiency. This further reduces the spacing between the condenser lens and PV cell, resulting in an extremely compact system.

Furthermore, the extra energy generated by locating the PV cell about midway between the optical condenser and its focal point allows the user the option of sending the surplus energy to a power grid (potentially generating extra income for the owner) or redirecting the energy to a backup storage device, such as a battery or a capacitor, for later use.

The longer the focal length of a lens, the larger the magnification of an image formed by the lens. Similarly, the angular extent of an image is magnified for a longer focal length lens, which increases the sensitivity of alignment and rigidity required of a lens system. A longer focal length lens can be described as having a longer lever arm of the image formed by the lens. A given displacement of an object off-axis (or a misalignment of a lens) results in a greater lateral displacement of the image in the image plane. For a given focal length lens, the lever arm is greater in the focal plane than it is mid-way to focus due to the longer distance to the focal plane or near focal plane. Therefore, when the PV cell is not precisely aligned along the optical axis of the lens and/or the lens is not precisely orientated in the direction of the sun, lateral displacement of the concentrated energy at or near focus is magnified compared to a location midway from focal point. Misalignment between the condenser lens and PV cell displaces the solar energy footprint off-axis to the condenser lens, resulting in an energy footprint that partially or completely falls off the PV cell. A PV cell located at or near the focal point thus suffers from high sensitivity to alignment and tracking. Therefore, a longer lever arm will displace the concentrated solar energy on the PV cell such that a very rigid structure to support the system and precise tracking is required, leading to a bulkier system that is heavier, more complex and more expensive. Thus, a longer lever configuration (where longer lever arm refers to a PV cell located at or near the focal point as opposed to midway to the focal point) will suffer greatly reduced power generation and power fluctuations due to flexure, wind bounce, vibration, and non-ideal solar tracking.

By locating the PV cell at or near the mid point to the focal point, the electrical power output is less sensitive to structural bending or sagging, or misalignments that may be introduced during assembly or develop over time. Therefore, a system that uses a PV cell located midway from focus can be constructed from less expensive materials and be less rigid, bulky and heavy as a system where the PV cell is located at or near the focal point. Also, due to the previously described greater uniformity of illumination, shorter focal length condenser lenses can be used, thereby reducing the lens to PV cell spacing even further. A shorter focal length condenser lens enables the PV cell to be located in close proximity to the condenser lens or lenslet array.

For solar tracking applications, the solar tracking device is not required to be as precise, thus allowing the user to use a low-cost tracking system or even a non-tracking system, such as is commonly employed with stand-alone PV panels. A non-tracking system does not follow the sun and therefore does not benefit from maximum collection efficiently throughout the day. Many of today's solar panel systems do not track the sun, however, and are still useful in a wide range of applications. By locating the PV cell midway from the focal point, non-tracking is possible for certain applications. However, by locating the PV cell at or near the focal point, tracking is certainly required; otherwise the concentrated solar energy would be completely displaced off the PV cell for the majority of the day. Accordingly, in the embodiments of the invention, non-tracking or lower precision tracking can be implemented, thus resulting in a lower cost platform. The lateral displacement of concentrated solar energy is not offset much by imperfect solar tracking, which is not the case when the PV cell is located at or near the focus, where the entire energy footprint can be displaced off the PV cell with moderate wind loading on the structure, vibrations or imperfect solar tracking.

When the PV cell is located at or near the focal point, the spacing between the condenser lens and solar cell is larger, therefore requiring a larger and bulkier support frame, The larger support frame is required to be more rigid than a support frame for a mid-focus configuration. When the PV cell is located midway from the focal point, the spacing between the condenser lens and solar cell is minimized; therefore, the support frame will be more rigid, less bulky, lighter and less expensive.

In addition, the sensitivity to misalignments of the solar cell and condenser lens has little effect, resulting in a more robust system that produces higher power production levels that do not fluctuate. Thus, additional benefits to the solar panel condenser apparatus described herein include, but are not limited to, the following. An apparatus whereby the PV cell is located midway from focal point results in an energy producing system that is lighter, more compact and more robust, and that will produce greater peak and average power levels. Additionally, such a system is lower in cost and less complex. It operates at a lower temperature and therefore operates at a greater efficiency, with greater uniformity of illumination, and with little or no power fluctuations due to dynamic misalignments from wind loading or vibration. In such a system, there is minimal power loss from static optical misalignments which occur during assembly or are developed over time. Additionally, there is minimal power loss from non-ideal tracking system.

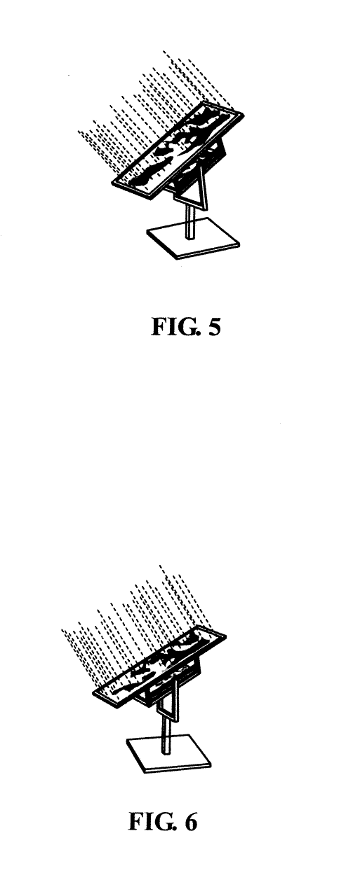

By reducing the separation distance between the condenser and solar cell to a few inches or less (see FIG. 5 and FIG. 6), it may be practical to use the solar condenser for very large area solar panel applications including, but not limited to, rooftop systems for home or industry use and eventually sub-stations. By making the optical condenser available in collapsible sections it can be used to increase the output of small portable solar panels by a factor of about 2 to 3.

The optical condenser substrate can be made from inexpensive plastic or glass. The optical focusing or light bending is achieved by forming structures on the surface of the condenser optic. The condenser optic is not limited to a Fresnel lens, but a modified Fresnel lens can be used with extreme focusing power where aberrations are not as detrimental as they would be in an imaging application.

The solar condenser invention includes fabrication methods for manufacturing the solar condenser optic. In order to make large area condenser optics, a mold is machined in metal or any other suitable mold substrate. The master mold contains arc structures that are sections of larger rings. Therefore, very large condenser optics can be fabricated without the requirement of a very expensive large mold for imprinting the surface refracting structures. Other methods of fabrication, include, but not limited to, laser or chemical etching, lithography, diamond turning, machining, stamping, pressing, embossing or any other replication techniques. The optical condenser can be made very large by fabricating sections of the optic rather than a continuous surface. Therefore, a condenser can be made in small sections and packed into a portable transport case.

A lightweight lattice frame or other framework is constructed above the solar panel to hold a single solar condenser element or an array of smaller solar condenser sections making up a larger area. The solar condenser sections can be packaged in a portable carrying case for field use, to lower shipping costs or aid in installation. The solar condenser sections can be used to make a larger array for large area solar panel applications, including, but not limited to, complete rooftop systems.

The proximity of the solar condenser can be made small enough to build the condenser into the frame of the solar cell housing (FIG. 6). The framework supporting the condenser system can be carbon fiber or other lightweight material.

The solar condenser can be mounted in close proximity (about 2 to 4 inches) to the solar cell using a condenser having a short focal length (FIG. 6). The solar cell may be mounted mid-way or closer than the focal plane of the condenser optic. This allows the complete solar panel condenser apparatus (including optical condenser, solar panel, cold plate) to be mounted into a common frame.

In another embodiment, the optical condenser contains a dual purpose coating that (1) maximizes the transmission through the condenser optic over the wavelength range that contributes to photo-generated current as well as (2) blocks longer wavelength (or other) regions of the solar spectrum that do not contribute to useable current. The coating can be an important aspect of the condenser, as it can control the region of the solar spectrum that is incident on the solar cell. Photons outside the spectral response of the solar cell substrate contribute to heat and therefore loss of efficiency.

The broadband anti-reflection (AR) coating is optimized for the spectral response of the photo-voltaic substrate. A low-pass (LP) (cut-off or blocking filter) coating is designed in conjunction with the anti-reflection coating. The low-pass anti-reflection (LP-AR) coating will reduce reflection losses (from 5% to less than 1%) as well as block wavelengths that do not contribute to useable current and only contribute to heating the substrate material therefore reducing efficiency. The combined LP-AR coating can be optimized for other solar cell materials not limited to silicon based solar cells.

Unused wavelengths in the infrared for example will be blocked by the outer LP-AR coating on the solar condenser. Heating of the substrate is a large factor in reduced efficiency; therefore, the LP-AR coating in conjunction with the optional cold-plate (CP) will minimize efficiency losses due to heating and maximize the gain of the solar condenser. The benefit of this approach is that the current output of the solar cell remains a linear function (i.e., proportional to the number of incident photons) over a larger range prior to saturation. The LP-AR coating and CP enable the maximum number of photons captured by the large aperture solar condenser to be absorbed by the solar cell substrate resulting in useable photo-generated current.

The coating may also take the form of a bandpass coating that is specifically designed to match the spectral response curve of the solar cell substrate. In this configuration the bandpass coating has the highest transmission possible across the spectral bandwidth of the solar cell. The bandpass coating has band edges that are as steep as possible to provide maximum blocking of unwanted wavelengths outside the bandwidth of the solar cell. The bandpass coating blocks unusable photons that only contribute to heat and loss of efficiency and do not contribute to useable current. The bandpass coating is an alternative to an anti-reflection coating and a low-pass filter. Any other bandpass, blocking, low-pass or anti-reflection coating can be applied to the solar condenser optic.

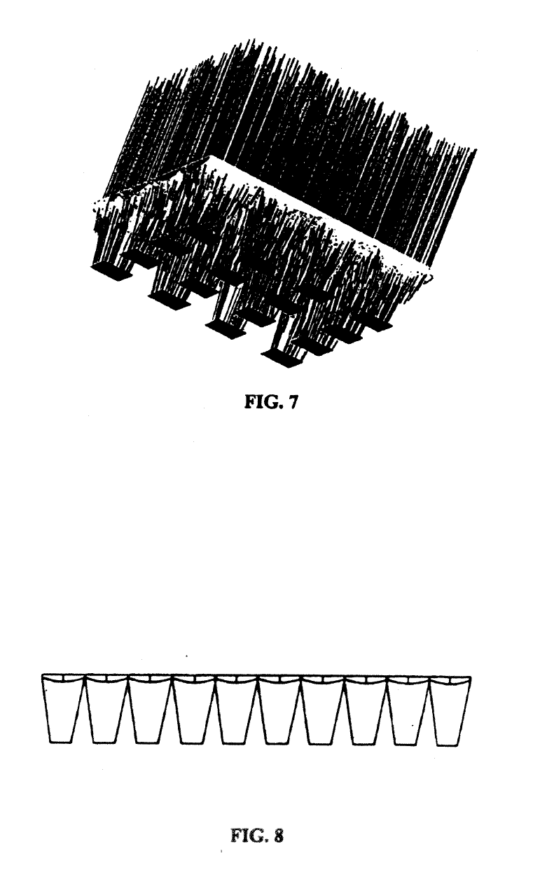

In another embodiment, the optical condenser comprises smaller aperture condenser lenses or lenslets (see FIG. 7). One benefit of this design is that a focal ratio of F/1 results in a much shorter focal length for a smaller aperture lens than for the full aperture condenser (F/number=focal length/aperture); therefore, the PV cells can be located much closer to the optical condenser, e.g., within a separation distance of about 3 inches or less, or within a separation distance of about 1 inch. This arrangement makes the solar condenser apparatus compact enough to be used for roof mounted and other systems.

The closer the PV cell can be placed with respect to the optical condenser, the less the sunlight distribution changes with sun angle. Larger focal ratios and larger separations between the optical condenser lens and PV cell result in the displacement of the solar irradiance mapped onto the PV cell throughout the day. Therefore, low F/number and close proximity are preferable to maximize the benefit of the solar condenser efficiency. Accordingly, a compact arrangement reduces the advantage of having a tracking system. A tracking system, however, remains an optional feature in order to keep the solar condenser apparatus pointed at the sun such that the projected collection area is maximized throughout the day.

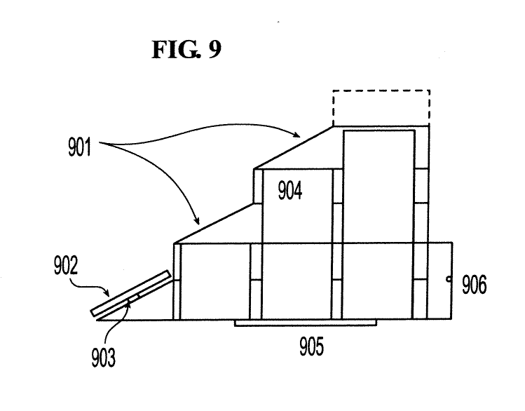

In this matrix configuration a two-dimensional array of smaller photo-voltaic solar cell elements (PV-Cells) are used instead of a large continuous solar cell panel (see FIG. 8). For a 1-meter by 1-meter optical condenser lens and a 0.5-meter by 0.5-meter photo cell area, the solar-cell can be made in smaller sections and be mounted in an array where each condenser lenslet is located above a PV-Cell. Here, the F/number of the solar condenser lenslet elements is not required to be as low as F/0.25 in order to achieve 3-inch or less separation (as is the case for the large aperture solar condenser), therefore simplifying manufacturing. Using the solar condenser technology as a single aperture light collector or collector array, the effective light collection area of the 0.5-meter by 0.5-meter solar cell is equivalent to the 1-meter by 1-meter light collector, therefore increasing the output of the solar cell by a factor of 4 (FIG. 9).

The solar condenser array can be made in small aperture lenslets ranging in size from, but not limited to, 25 millimeters up to 1 meter. Accordingly, manufacturing, assembly, shipping and installation costs are greatly reduced. The solar condenser array can be scaled to any practical size (many meters in size) using a two-dimensional array of PV-Cells and optical condenser lenslets. The amount of useable electrical power generated is increased by a factor of 2, 3, 4 or potentially more (depending on the ratio of solar collector to solar cell area, focal ratio and spacing) compared to an equivalent sized solar panel without the solar condenser technology.

The solar condenser array can be made very compact and produce four times more electrical current than an equivalently size solar panel. In addition, the condenser array in its compact arrangement eliminates the need to track the sun. However, an optional tracking system is part of the solar condenser technology for applications where tracking is beneficial. A tracking device maintains maximum effective collection area throughout the day. In addition a cooling plate further increases the efficiency of power conversion from incident photons into useable electric current.

In another embodiment, which can be seen in FIG. 9, the solar condenser and solar cell systems 902 can be mounted vertically to a tower structure to increase the collection area in a smaller footprint on the ground. The tower structure comprises staggered shelves 901 (similar to a layer cake) where each shelf further comprises solar cells tilted at an angle to maximize collection area. For larger power stations where a number of solar towers are required, each solar tower structure would be arranged geometrically to minimize shadowing from neighbor towers from sunrise to sunset. Each vertical tower can be rotated about its base 905 to maintain optimum angle of incidence between the sun and the solar cell. Each solar condenser and panel can also be mounted, optionally, on a pivoting base 903.

The inside of each solar tower comprises energy storage banks 904 such that required power can be supplied throughout the night, cloudy or rainy weather conditions. Banks of capacitors, batteries or other storage devices are arranged within the solar tower. Electrical power can be drawn from super capacitors by high-speed switching circuits that draw electrical current from the super capacitor banks without discharging them completely. Capacitors avoid additional energy conversion that takes place within batteries. Electrons that are generated by the solar cell are stored in the super-capacitor bank and drawn away as usable electrical current by power distribution circuitry. Batteries exhibit longer storage lifetimes without self-discharging over capacitors or super capacitors; however, super capacitors have longer lifetimes and are less environmentally hazardous. Capacitors by nature can be discharged in a few seconds, therefore switching circuitry and regulating circuitry draw current from capacitors in a controlled fashion without completely discharging them. Banks of capacitors, super capacitors, batteries or combination thereof are used to maintain constant supply of power as needed during times of reduced available solar energy. The energy storage bank is charged using excess electrical current available during times of peak solar electricity generation.

The energy storage reservoir within the solar tower consists of any combination of the following: batteries, super-capacitors, fluid or mechanical storage (described in Solar Electric Generator patent application).

The self-contained solar energy tower includes solar collection optics and solar cells mounted to shelves on the exterior of the tower for generating electrical power and a large chamber within the tower consisting of electrical storage units. Access to the chamber can be gained via an access door 906.

For rooftop mounted solar condenser and solar cell units, the energy storage reservoir may consist of an energy storage closet or shed that can be installed in the yard, within a garage or basement.

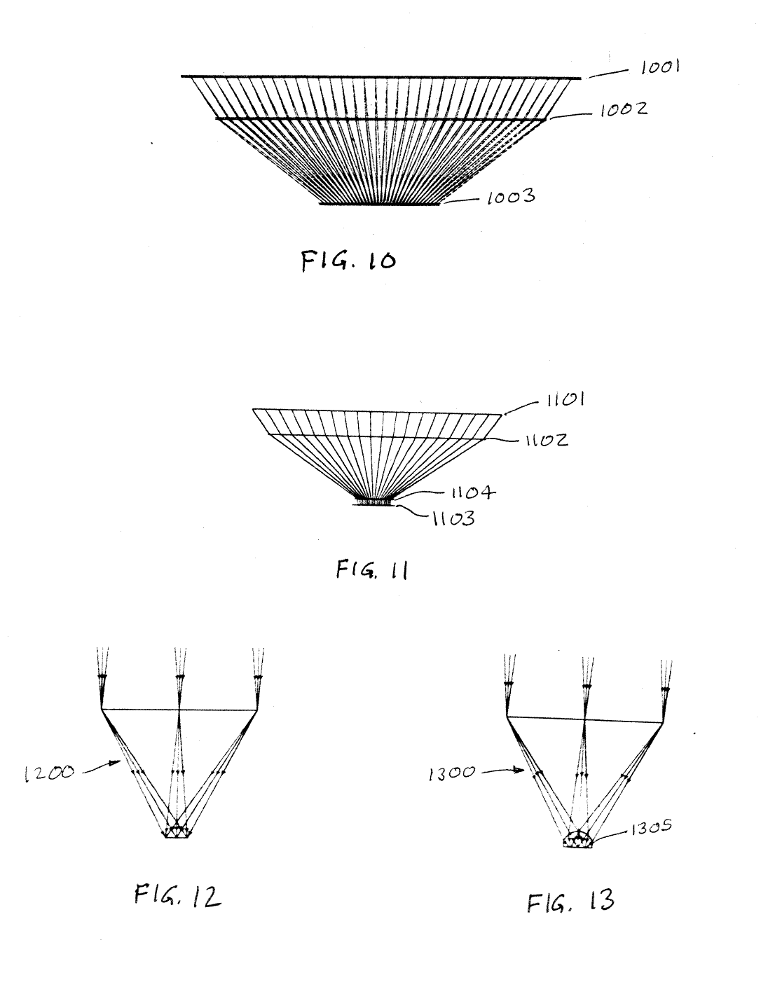

In another embodiment, shown in FIG. 10, a second Fresnel lens 1002 may be placed behind and approximately 1 inch from the first Fresnel lens 1001. As with the first Fresnel lens 1002, the solar cell 1003 may be situated midway between the second Fresnel lens 1002 and the focal point of the second Fresnel lens 1002 to produce another gain in collection area by any practical magnification ratio. The second lens 1002 adds little to the distance between the first Fresnel lens and the solar cell in the previously described embodiment, making it a compact and practical solution suited, e.g., to rooftop systems and other home generation units, and high power solar electric applications such as small power sub-stations.

By placing a second lens approximately 1-inch or up to midway to focus from the first lens the solar cell can produce a gain in collection area by a factor of 10 up to 100 using silicon based solar cells and a gain in 500 to 1,000 using smaller high efficiency broadband solar cells GaAs/Ge, GaInP2/GaAs/Ge, GaInP2/GaAs/Ge, GaInP2/GaAs/Ge, GaInP2/GaAs/Ge. The total separation between the first lens and the solar cell is about 5 inches making it a practical and compact solution ideally suited for power generation units. The large power gain from the solar cell is also well suited to high power solar electric applications such as small power sub-stations.

The location of the Solar Condenser Reducer results in highly uniform energy distribution in the plane of the solar cell, which optimizes power generation. Non-uniform illumination of the solar cell creates hot spots, resulting in electron or current bunching which lowers the efficiency of a solar cell. Therefore an additional advantage to the Solar Condenser Reducer invention is greater uniformity of solar concentration as well as greater acceptance angle. Combined with the compact geometry results in advantageous solar electric module that is highly efficient, lightweight, compact and lower cost. The Solar Condenser Reducer enables very short effective focal lengths to be achieved over a single Condenser lens resulting in a highly compact geometry.

The present invention incorporates available high efficiency solar cells of the following example materials: GaAs/Ge, GaInP2/GaAs/Ge, GaInP2/GaAs/Ge, GaInP2/GaAs/Ge, and GaInP2/GaAs/Ge.

FIG. 11 shows another refinement of the present invention. The arrangement in FIG. 11 is similar to that of FIG. 10, with first and second Fresnel lenses 1101 and 1102, respectively, and solar cell 1103. However, a collimating lens 1104 is located at the same location as the solar cell 1003 in FIG. 10, directly in front of the solar cell. Collimating lens 1104 produces a more uniform spread of light onto the solar cell as well as collecting a large solid angle of ambient solar flux scattered in the atmosphere, the surrounding sky, and clouds. This results in use of a greater amount of available solar flux. In addition, this approach increases the amount of electricity produced on cloudy or overcast days.

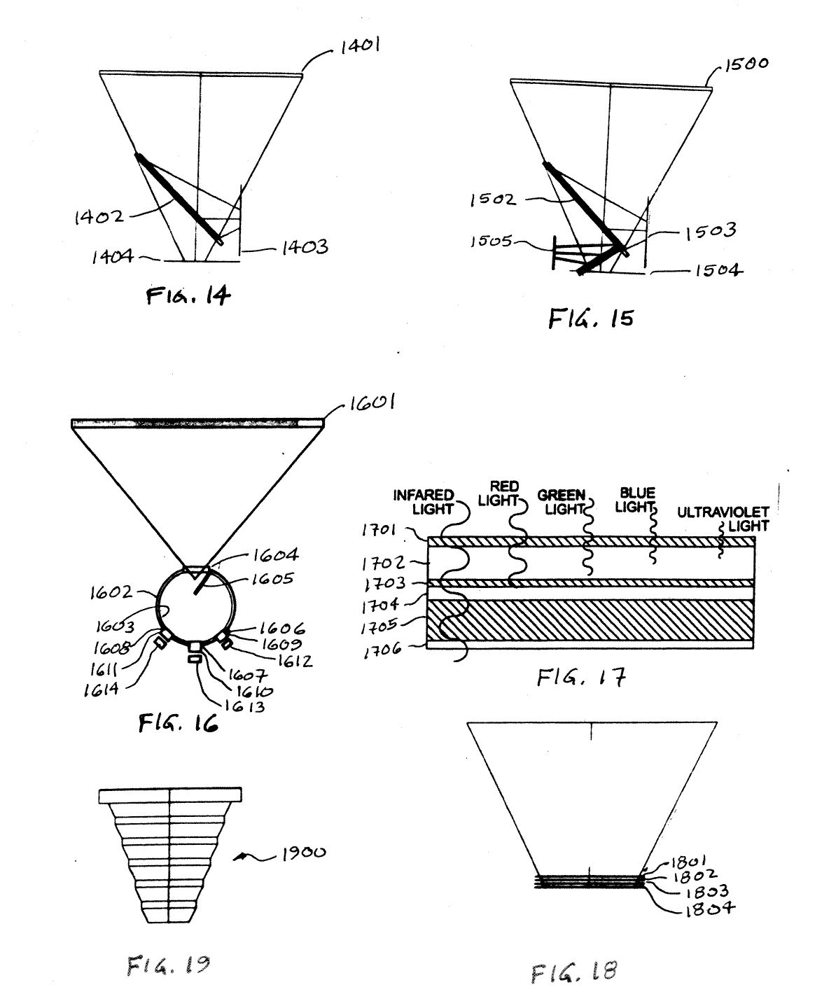

FIG. 12 shows a side view of a solar condenser 1200 without a solid immersion lens. FIG. 13 shows a side view of a solar condenser 1300 with a solid hemispherical immersion lens 1305. The configuration of FIG. 13 increases the angle of sky concentrating on the solar cell, therefore increasing the electrical power produced from a conventional solar cell.

Because, as of the date of filing this application, the cost of a solar cell unit of a given surface area far exceeds the cost of Fresnel lenses covering the same surface area, the reduction in area of the solar cell units in relation to the surface exposed to the sun, using the Fresnel lenses can cause a dramatic drop in fabrication costs for a solar array.

FIG. 14 shows a large aperture solar collecting lens 1401 used to collect solar radiation and bring it towards a focal point, with a beam splitter 1402 situated between the solar collecting lens 1401 some distance from the focal point of solar collecting lens 1401. The beam splitter 1402 contains a dichroic coating such that the visible portion of the solar spectrum transmits through the beam splitter 1402 while the infrared portion of the solar spectrum is reflected at the surface of the beam splitter 1402. A visible solar cell 1404 is located in the direct path of the transmitted solar radiation while an infrared solar cell 1403 is oriented at 90 degrees to receive the infrared portion of the solar spectrum. The addition of a single beam splitter element 1402 enables a much larger portion of the solar spectrum to be converted into useable electric power. Previous methods do not make use of multiple portions of the spectrum and the portion of the solar spectrum that falls outside the spectral response of the solar cell contributes to heat. This heating of the substrates reduces the efficiency of the solar cell and therefore has limited the utility of concentrating PV systems until now. Previous methods require coatings that reject the unused spectrum and discard it. The present invention increases the conversion efficiency of a solar electric system by extending the solar spectrum that is converted into electricity rather than discarding it. In addition, the gain in collection efficiency is increased by a factor of 500. The beam splitter component can be constructed of glass or plastic and coated with a dichroic beam splitter coating optimized for 45 degree angle of incidence or any other practical angle suitable for assembly.

The benefits of the present invention are manifold. A larger collecting aperture can be used over present technology without increasing the heat load. Most solar cell manufacturers rate the performance of their solar cell using a standardized 1,000 Watts per square meter. This standard assumes the entire solar spectrum is incident on a solar cell. The beam splitting innovation reduces the bandwidth required of each solar cell and allows a greater flux to be collected by the concentrator while still operating within the dynamic range of the solar cell without saturating and overheating.

An advantage of the present invention is the collection of solar energy and concentrating onto more than one solar cell. A beam splitter optical element separates the solar spectrum into multiple regions that are within the optimal bandwidth of each respective solar cell. A larger collection aperture can be used without overheating the solar cell material. The primary advantage of this technology over current technology is the separation of the solar spectrum into bands. Light that falls outside the spectrum of a solar cell is unused and contributes to heat. The present invention separates the solar spectrum into bands such that each band is directed to a separate solar cell optimized for that portion of the spectrum. This enables inexpensive solar cell technology to be implemented without requiring expensive multi-layer solar cell technology. Two or three solar cells can be used to cover a greater portion of the solar spectrum therefore increasing the efficiency of the integrated device to 40%, 50% or larger. With the addition of the concentrator optic, the amount of semiconductor material required is reduced.

As shown in FIG. 15, two beam splitters 1502 and 1503 can be used to separate the spectrum into three components, one each for solar cells 1503, 1504, and 1505. More than the two beam splitters shown can be used to generate electricity from an even greater range of the light spectrum.

FIG. 16 shows a spherical light trap 1602 used to intercept a solar beam from solar light collector 1601 prior to focus. The spherical light trap 1602 is similar in nature to an integrating sphere. However, in the case of the spherical light trap 1602, the inner surfaces 1603 of the sphere are polished and coated with a highly reflective mirror coating. At one end side of the spherical light trap is an aperture 1604 through which sunlight enters. The spherical light trap 1602 may be rotated a few degrees such that the aperture is not perpendicular to the incident beam. Light enters the light trap 1602 and undergoes multiple reflections within the sphere in a circular pattern traveling around the sphere. A light baffle 1605 that is also polished and coated with a highly reflective coating may be located near the center of the entrance aperture 1604 tilted such that any light that traverses the inside of the spherical light trap 1602 does not exit the sphere at the entrance port or window 1604, instead it is reflected by the entrance baffle 1605 and continues to travel around the spherical light trap 1602.

Ports 1606, 1607, and 1608 are located on the opposite sides of the spherical light trap 1601 from the entrance aperture 1604. Port 1607 is an aperture that contains a lens 1610 that consists of a radius of curvature that matches the inside radius of the spherical light trap 1602. Lens 1610 may be coated with a band pass coating or in this case a partial coating that transmits visible light but reflects infrared light. Visible light passes through the lens 1610 and exits the spherical light trap 1602. Lens 1610 collects all the visible light exiting port 1607 and brings it to a focus. A visible light solar cell 1613, using silicon based solar cell or other visible light solar cell material is located mid-way between the lens 1610 and the focal point of the lens 1610. A second port 1606 contains a lens 1609 also having a radius equal to the radius of the spherical light trap 1602. However, this lens has a coating such that infrared light is transmitted and exits port 1606 while visible light is reflected and continues around the spherical light trap 1602 until it exits Port 1. Lens 1609 collects and focuses all the infrared light onto an infrared solar cell 1612 located mid-way between the lens 1609 and the focal point of the lens 1609.

The spherical light trap 1602 may range in size from 4-inches in diameter up to 24-inches for high power systems. In the 4 to 6-inch diameter sphere range the exit ports may range in size up to approximately 1-inch in diameter. The band selecting port and associated lens is a 1-inch aperture and focuses light onto a solar cell approximately 0.5 inches across. The spherical light trap 1602 separates two or more portions of the spectrum.

The collector lenses 1609, 1610, and 16011 may range in size from 4-inches across up to 1-meter across. The aperture of the solar collector can therefore be 1-meter and reduced down to 10 mm resulting in an aperture gain of (1,000/10)²=1,000. Coupled with the additional gain of collecting multiple regions of the solar spectrum adding an additional 10-20% on collection efficiency of the combined solar cell doublet. This produces a 100% increase or factor of 2 in electrical conversion efficiency coupled with the 1,000 gain in collection efficiency results in a 2,000 gain in electrical output from a single solar cell 10 mm in size.

The spherical light trap 1602 can be molded in two halves such that each half can be coated with a highly reflective coating. Each half of the sphere is a fine polished surface. The port lenses 1609, 1610, and 1611 can be mass produced molded lenses and coated. The two halves of the sphere are attached and the port lenses 1609, 1610, and 1611 are inserted into apertures 1606, 1607, and 1608 with flanges. The solar cells 1612, 1613, and 1614 are then attached to the output ports.

Another innovation of the solar sphere light trap is the geometry of the sphere, entrance aperture, baffle and exit ports such that light enters the sphere at an oblique angle and such that total internal reflection occurs at each reflection within the sphere. In this configuration no reflective coating is required inside the sphere and reflection losses due to absorption are eliminated. The inner surface of the spherical light trap 1602 may be left uncoated such that total internal reflection occurs at each reflection as light travels around the perimeter of the sphere. In a second configuration the inner surfaces of the sphere are coated with a highly reflective silver coating 99% reflective.

The spherical light trap 1602 is situated between the collecting lens 1604 and focus of the collector 1601. The spherical light trap 1602 may be made as a single unit or a small or large array of collector lenses or mirrors making up a 100 KW up over 1 MW solar power system. Each collector lens has an associated light trap and multiple solar cells receivers. The spectral collection efficiency is increased by at least a factor of 2 and the amount of semiconductor material is reduced by at least two orders of magnitude. The cost per watt of the spherical light trap is small compared to the price per watt of solar cell material.

This invention separates the spectrum into bands that match the optimized bandpass of the solar cell within each selection port. The spectrum is separated into multiple bands such that light that is not within the spectral response of a given solar cell device is diverted to a different port where it is collected by a suitable solar cell. Therefore a larger portion of the solar spectrum is used an converted into electric power. Light that was contributing to heat in the past is now useable electricity.

The solar condenser of the present invention can be used in conjunction with, for example, the Thinned Solar Cell, an invention of the same inventors, which is disclosed in U.S. application Ser. No. 11/889,369. The Thinned Solar Cell invention increases the inherent efficiency of photo-voltaic solar cells to a potential 90% peak from the existing 25%. By combining the Thinned Solar Cell with the solar panel condenser apparatus, the electrical output, for a given area of solar cell material, can be increased by a factor of 12.

Another embodiment of the invention is multi-band solar stack. FIG. 17 shows that by reducing the thickness of the outer layer of the PV material, a larger percentage of photons are able to reach the vicinity of the depletion region established by the doped layers within the silicon and contribute to useable electricity. In FIG. 17, 1701 represents an anode, 1702 represents a P doped silicon layer, 1703 represents a depletion region, 1704 represents an N doped silicon layer, 1705 represents a silicon substrate layer and 1706 represents a cathode.

The thinned solar cell can then be coated with an anti-reflection coating to reduce the number of lost photons resulting from reflections at the surface of the material. These surface losses are due to the large Fresnel reflections at the boundary between air (index of refraction n=1.0) and silicon (index n=3.6). An ideal anti-reflection coating would have an index of refraction equal to the square root of the substrate index or n=1.9. An example of an anti-reflection coating applied to silicon can include hafnium dioxide, titanium dioxide or silicon nitride. Existing solar cells are often coated to reduce surface reflections. Here the anti-reflection coating is applied to a thinned solar cell.

Typically PV material used as a solar cell for power generation is used in forward bias configuration. The photo-generated current is linearly proportional to the number of incident photons over a large range. Noise electrons (or noise current) are also generated which do not contribute to useable photo-generated current, therefore limiting the output of a solar panel. Some of the noise current is generated when the material operates at elevated temperatures. The thinned solar cell includes a cooling layer that consists of a semi-conductor Thermal Electric (TE) cooling device of the Peltier type, liquid or any other cooling technique to minimize noise current such as thermally generated electrons typically associated with Johnson noise or resistive heating. The cooling layer or cooling jacket is bonded to (or part of) the electrical backplane of the photo-voltaic substrate. The cooling system will lower the operating temperature of the solar cell using a portion of the generated electrical output, therefore lowering the noise and ultimately increasing the efficiency of the solar cell.

The thickness of the substrate can be reduced using chemical, mechanical or any other means of etching (liquid or dry), grinding or polishing (e.g., chemical, mechanical, chemo-mechanical, ion bombardment). This will increase the efficiency of existing solar cells by 100% or greater.

The process of thinning doped silicon has been successfully applied to Charge Coupled Devices (CCD) imaging detector arrays where greater than 90% peak Quantum Efficiency (QE) has been achieved. The electrical biasing of the silicon material in a CCD is not equivalent to that of a solar cell which is typically “forward biased” for electrical power generation. A solar cell would not produce a low noise imaging sensor. Noise in a solar cell arises from electrons that are generated in the material but do not contribute to useable electricity. Schott and Johnson noise limit amount of photo-generated electrons that contributes to useable current. Therefore, thinning a solar cell may not have the gain or increased efficiency as great as that experienced in CCD imaging sensors. However by thinning existing solar cells it is possible to increase the percentage of incident photons that are absorbed at the desired depth in the doped silicon material therefore contributing to larger current densities and increasing the efficiency of existing solar cells at a low cost.

FIG. 18 shows a thinned solar cell stack 1800 optimized for the portion of the solar spectrum that is most efficient for each material. The thinned solar cell stack 1800 enables the first (top) solar cell 1801 to absorb only the portion of the spectrum that the material is optimized for. The remainder of the light passes through the first cell 1801 to the next layer which is a separate cell 1802 situated underneath the top cell 1800. The next portion of the spectrum is captured by the second cell 1802 in the stack and the remaining unused light passes through cell 1802 to the next cell 1803, with the remaining light passing through cell 1803 to cell 1804 at the bottom of the stack. The invention is not limited to four cells, but any number of cells may be stacked in this manner.

The bandgap of each cell in the stack 1800 is optimized for the portion of the spectrum that it is intended to capture and convert to electricity. The advantage of this approach, i.e. building a stack of thinned wafers optimized for a portion of the spectrum that the material offers maximum efficiency when converting incident photons to electrical current. This innovation eliminates the need for expensive and obscure PV materials that exhibit an extended bandgap or multiple band-gaps within the material. This approach uses a stack of thinned solar cells where each cell capture a portion of the solar spectrum converting that band of light to electricity and transmitting the remainder of the spectrum to the next cell in the stack. The result is a solar cell stack 1800 that extends the conversion of light to electricity over a much broader spectrum than current silicon solar cells and significantly less expensive than multi-junction solar cells. The efficiency of such a solar cell stack could exceed 50% by capturing a larger portion of the solar spectrum than a standard silicon based solar cell or multi-junction cell and less expensive than a multi junction cell.

The Hybrid Solar Condenser or funnel concentrator array increases the effective solid angle of received sunlight including stray sunlight from the surrounding sky and therefore increases the output power of PV cells. By combining a concentrator lens and a large solid angle funnel collector the amount flux collected is increased. The solar funnel condenser system incorporates an array of solar condenser optics, an array of wide angle cone or funnel concentrators and a sparse array of solar cells. The concentrator lenslets collect sunlight over a larger aperture than the solar cell on its own. The solar funnel captures sunlight and sky background over a large solid angle therefore increasing the total flux captured by the concentrator system above the flux gathered by the concentrator on-axis. The collector lens may be located at the top of a grid and may seal the concentrator unit which protects the reflective coating on the funnel concentrator walls. As a result the output is increased as well as the efficiency over conventional solar electric modules. The taper angle of the funnel concentrator is larger than F/1 to avoid retro-reflection of light rays back out of the system. The aperture of each lens is chosen to ideally suit a given solar cell. A heat sink is in contact with the PV cell and is used to transfer heat away from it, thereby increasing the operating efficiency and minimizing the adverse effect associated with a larger effective collection area.

Since the hybrid optical funnel concentrator is not an imaging optic but rather a light collecting and concentrator optic, it can be made with a very short focal length (or low F/number) in order to minimize the separation between the solar concentrator and solar cell to a few inches. The optical concentrator can take the form of a Fresnel lens, a computer generated holographic optic, or any other refractive, diffractive or hybrid optical element. The primary goal of the concentrator optic is to collect solar energy over a larger effective area than the area of the solar cell by condensing the light onto the PV solar cell. The solar concentrator can be machined, molded or pressed into glass or plastic and can replace the existing cover glass of a solar module.

Large-array hybrid optical concentrators can be fabricated from inexpensive glass or plastic material that is highly transmissive over a large wavelength range and which can withstand ultraviolet exposures over many years. As shown in FIG. 19, the faceted funnel concentrator 1900 is designed to bend light rays that fall outside the area of the solar cell and redirect them to intercept the solar cell.

Additional optical geometries of the reflective cone include multiple taper geometries that avoid retroreflection of sunlight at large angles of incidence as well as multi-faceted side wall funnel geometries for optimal light guide onto the solar cell.

The solar condenser increases the electrical power output of a conventional solar cell configuration using a concentrator lens that is larger in diameter than the solar cell. The hybrid solar condenser further increases the electrical power output of the funnel concentrator over the lens-only concentrator by increasing the combined concentrator solid angle which will concentrate a larger fraction of the sky background onto each solar cell.

The front end lens snaps into a frame and the solar cell unit snaps into the back side of the module sealing the unit. The side walls of the solar condenser also act as reflectors to concentrate stray light from the background sky onto the solar cell unit. This embodiment of the solar condenser results in a compact, lightweight, highly efficient solar electric module.

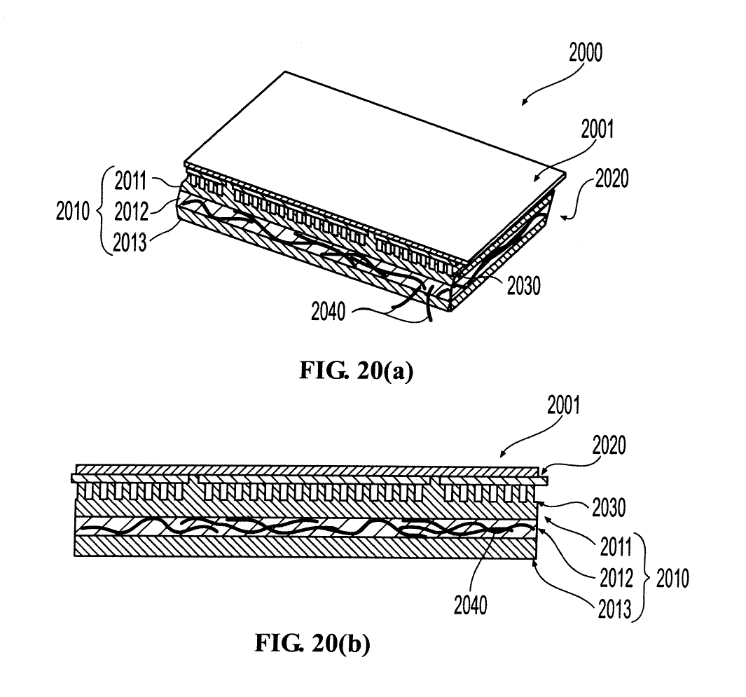

As shown in FIGS. 20(a) and (b), the present invention further may include a new semiconductor solar cell device 2000 that contains a capacitive electrical storage unit 2010 of equal area to the area of the solar cell 2001 and mounted behind the cell 2001 itself. Each solar cell 2001 within a panel module contains a dedicated capacitor 2010 that stores excess electrical charge generated during the day that can be controlled and discharged slowly during cloudy periods or throughout the night. Rather than a large bank of batteries and or capacitors, the solar photon capacitor 2001 is built into each solar cell 2000. A circuit controls the distribution of electricity to the user or capacitor depending on the load and time of day. The solar cell capacitor bank is charged during sunny periods and discharged as useable electricity throughout the night or cloudy periods, offering the potential for 24-hour solar electricity.

Solar cell 2001 is mounted on ground plane 2020, which is in turn connected to the capacitor 2010 by inter-connect grid 2030. Inter-connect grid 2030 is mounted on upper capacitor plate 2011 of capacitor 2010. Capacitor 2010 comprises upper capacitor plate 2011 and lower capacitor plate 2013 separated by electrolyte layer 2012.

In one configuration, the solar cell capacitor is a separate capacitor component having equal cross-sectional area as the solar cell. The depth or length of the capacitor is designed to store a desired amount of electrical charge during the day which can be discharged throughout the night.

The present invention describes a new semiconductor solar cell device that contains additional semi-conductor structures and gates to enable the storage of electrical charge.

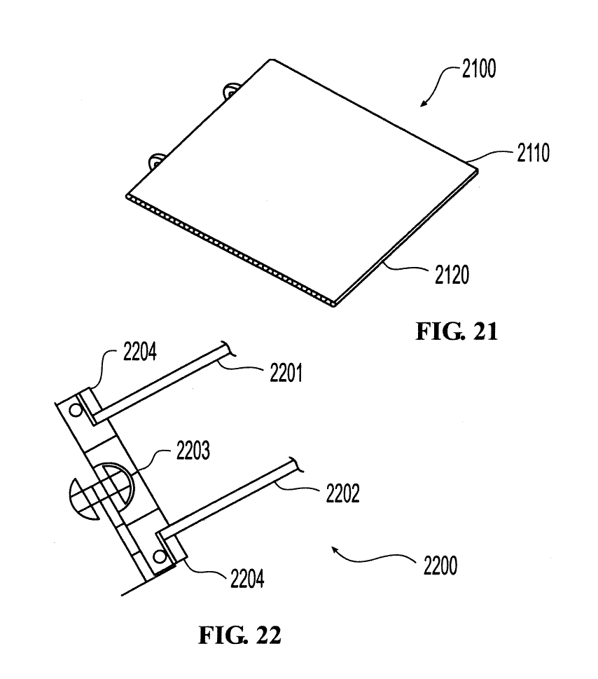

The solar cell photon capacitor has dual configurations such that the photo-electric effect can take place resulting in the conversion of photon energy into electrical energy continuously. As shown in FIG. 21, by modifying the solar cell device 2110 with semiconductor electrical traps 2120 surrounding the cell and mounted on the solar cell substrate 2120, electrical charge can be stored.

This new solar cell photon capacitor behaves similarly to a single pixel or picture element in a Charged Coupled Device imaging sensor. A large solar panel array can then be used to collect light and store light which can be converted into a usable image. The quantity of light stored in each solar cell pixel represents the light level in an image. This configuration of a solar cell array results in the construction of the world's largest CCD imaging camera which can be used in a variety of applications.

An advantage of the solar cell photon capacitor is the collection and storage of electrical energy during daylight ours. A portion of the electrical energy produced during the day can be used in real-time to produce usable electrical power. However, using the solar cell photon capacitor, a portion of the electrical energy produced during sunlight hours can be converted to electrical energy and stored within the backside of the solar cell device within internal isolated region.

The innovation of the solar cell photon capacitor is an all-in-one semiconductor 24 hour solar cell device that produces usable electrical power during night hours or cloudy periods as well as sunny periods.

FIG. 22 shows a solar roof 2200 according to the present invention. Lens array 2201 is maintained at a fixed distance from solar cell array panel 2202 upon which solar cells are mounted. Lens array 2201 is held at a fixed distance from solar cell array panel 2202 by frame 2203, with retainers 2204 used to attach each of the lens array 2201 and the solar cell array panel 2202 used to hold the assembly together. The frame may be made of vinyl, which is lighter and nonconductive compared to the aluminum frames commonly used on solar cell arrays.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the metes and bounds of the claims, or equivalence of such metes and bounds are therefore intended to be embraced by the appended claims.

1. A solar panel condenser apparatus comprising:
an optical condenser comprising a first Fresnel lens; and
a first photovoltaic cell mounted substantially parallel to the optical condenser and placed about midway between the optical condenser and the focal point of the optical condenser such that most of the light received by the optical condenser falls on the first photovoltaic cell.

2. The solar panel condenser apparatus according to claim 1, wherein the optical condenser comprises a second Fresnel lens.

3. The solar panel condenser apparatus according to claim 1, wherein the optical condenser further comprises a collimator lens.

4. The solar panel condenser apparatus according to claim 1, wherein the optical condenser further comprises a solid immersion lens.

5. The solar panel condenser apparatus according to claim 1, further comprising a second photovoltaic cell, and wherein the optical condenser further comprises a first beam splitter which divides solar light collected by the solar panel condenser apparatus into visible light and nonvisible light, such that at least a portion of the visible light falls on the first photovoltaic cell and at least a portion of the nonvisible light falls on the second photovoltaic cell.

6. The solar panel condenser apparatus according to claim 5, further comprising a third photovoltaic cell, and wherein the optical condenser further comprises a second beam splitter which divides the nonvisible light into beams of light optimized for generating electricity by the second and third photovoltaic cells.

7. The solar panel condenser apparatus according to claim 1, further comprising a faceted funnel concentrator located between the first Fresnel lens and the first photovoltaic cell.

8. The solar panel condenser apparatus according to claim 5, wherein the first beam splitter comprises a coating that reflects a portion of the light spectrum and allows another portion of the light spectrum to pass through the first beam splitter.

9. The solar panel condenser apparatus according to claim 6, wherein the second beam splitter comprises a coating that reflects a portion of the light spectrum and allows another portion of the light spectrum to pass through the second beam splitter.

10. The solar panel condenser apparatus according to claim 1, further comprising a spherical light trap located between the first Fresnel lens and the first photovoltaic cell, wherein the spherical light trap separates admitted light into multiple bands according to wavelength.

11. The solar panel condenser apparatus according to claim 10, wherein the spherical light trap comprises an entrance aperture and a first port.

12. The solar panel condenser apparatus according to claim 11, wherein a first bandpass lens through which as band of the admitted light passes is located within the first port and the first photovoltaic cell is located adjacent to the first lens.

13. The solar panel condenser apparatus according to claim 12, wherein the first photovoltaic cell is constructed of a material optimized for the band of admitted light that passes through the first bandpass lens.

14. The solar condenser apparatus according to claim 10, wherein the spherical light trap comprises a light reflective baffle.

15. The solar condenser apparatus according to claim 10, wherein an interior surface of the spherical light trap is coated with a reflective material.

16. A multi-band solar cell stack comprising:
a first solar cell fabricated of a material optimized for a first portion of a solar spectrum and directly exposed to sunlight; and
a second solar cell fabricated of a material optimized for a second portion of the solar spectrum,
wherein the first solar cell and the second solar cell are stacked; and
the first solar cell is of a thickness such that the portion of the second portion of the solar spectrum passes through the first solar cell to the second solar cell.

17. A multi-band solar cell stack according to claim 16 further comprising a third solar cell fabricated of a material optimized for a third portion of the solar spectrum,
wherein the three solar cells are stacked; and the second solar cell is of a thickness such that the portion of the third portion of the solar spectrum passes through the second solar cell to the third solar cell.

18. A multi-band solar cell stack according to claim 17 further comprising a fourth solar cell fabricated of a material optimized for a fourth portion of the solar spectrum,
wherein the four solar cells are stacked; and the third solar cell is of a thickness such that the portion of the fourth portion of the solar spectrum passes through the third solar cell to the forth solar cell.
